(19) United States
(12) Patent Application Publication
(10) Pub. No.: US 2026/0173606 A1
(43) Pub. Date: Jun. 18, 2026

(54) METHOD OF MANUFACTURING LIGHT-EMITTING DEVICE AND LIGHT-EMITTING DEVICE

(71) Applicant: NICHIA CORPORATION, Tokushima (JP)

(72) Inventors: Koji TAGUCHI, Anan-shi (JP); So SAKAMAKI, Anan-shi (JP)

(21) Appl. No.: 19/417,781

(22) Filed: Dec. 12, 2025

(30) Foreign Application Priority Data
Dec. 16, 2024 (JP) 2024-220271

(51) Int. Cl. H10H 29/01; H10P 74/00; H10W 10/00; H10W 20/44; H10W 80/00

(52) U.S. Cl. CPC H10H 29/0364; H10P 74/232; H10W 10/014; H10W 20/4435; H10W 80/334

(57) ABSTRACT

A method of manufacturing a light-emitting device includes heating, to a first temperature, semiconductor light-emitting elements including electrodes each including a portion formed of a first metal and a substrate including connection terminals each including a portion formed of the first metal; press-bonding the portion of the electrode to the portion of the connection terminal with a first pressure to form an intermediate body; and applying a second pressure between the substrate and the semiconductor light-emitting elements to bring the intermediate body to a second temperature and cooling the intermediate body. The electrode or the connection terminal further includes a metal multilayer film including portions formed of second and third metals. The first temperature is lower than a solidus temperature of the second metal, and the second temperature is the solidus temperature of the second metal or greater and a liquidus temperature of the second metal or less.

### CROSS-REFERENCE TO RELATED APPLICATIONS

This patent application is based on and claims priority to Japanese Patent Application No. 2024-220271 filed on Dec. 16, 2024, the entire contents of which are incorporated herein by reference.

### TECHNICAL FIELD

The present disclosure relates to a method of manufacturing a light-emitting device, and more particularly relates to a method of manufacturing a light-emitting device using flip-chip mounting.

### BACKGROUND

As light-emitting devices including semiconductor light-emitting elements become smaller and more functional, there is an increasing demand for high-density mounting of semiconductor light-emitting elements. Particularly, in the mounting of semiconductor light-emitting elements, flip-chip mounting in which semiconductor light-emitting elements are mounted and bonded to a circuit board through a plurality of bump electrodes disposed on the surfaces of the semiconductor light-emitting elements is used instead of a bonding method using wire bonding (see, for example, Patent Document 1).

In recent years, in this flip-chip mounting, as the mounting density of semiconductor light-emitting elements increases, the spacing between adjacent semiconductor light-emitting elements becomes smaller, and as the semiconductor light-emitting elements become smaller, the spacing between the plurality of bump electrodes becomes smaller. Therefore, high mounting accuracy is required. Additionally, because driving of the semiconductor light-emitting elements causes heat generation of the semiconductor light-emitting elements, and thermal stress applied to joints between the semiconductor light-emitting elements and the circuit board increases as the mounting density of the semiconductor light-emitting elements increases, strong and reliable bonding is required (see, for example, Patent Document 2).

### RELATED ART DOCUMENT

Patent Document

[Patent Document 1] Japanese National Publication of International Patent Application No. 2007-528588

[Patent Document 2] WO 2014/097645

### SUMMARY

According to an aspect of the present disclosure, a method of manufacturing a light-emitting device includes heating a plurality of semiconductor light-emitting elements and a substrate to a first temperature, each of the plurality of semiconductor light-emitting elements including a plurality of electrodes, the substrate including a plurality of connection terminals, each of the plurality of electrodes including a first metal electrode portion formed of a first metal, and each of the plurality of connection terminals including a first metal connection terminal portion formed of the first metal; aligning the plurality of electrodes and the plurality of connection terminals while maintaining the first temperature; press-bonding the first metal electrode portion to the first metal connection terminal portion with a first pressure to form an intermediate body after the aligning of the plurality of electrodes and the plurality of connection terminals; and applying a second pressure between the substrate and the plurality of semiconductor light-emitting elements to bring the intermediate body to a second temperature and then cooling the intermediate body, the second pressure being less than or equal to the first pressure. Each of the plurality of electrodes further includes a metal multilayer film including a second metal electrode portion formed of a second metal; and a third metal electrode portion formed of a third metal, the third metal electrode portion being positioned between the first metal electrode portion and the second metal electrode portion, or each of the plurality of connection terminals further includes a metal multilayer film including a second metal connection terminal portion formed of the second metal; and a third metal connection terminal portion formed of the third metal, the third metal connection terminal portion being positioned between the first metal connection terminal portion and the second metal connection terminal portion. The first temperature is lower than a solidus temperature of the second metal, and the second temperature is greater than or equal to the solidus temperature of the second metal and less than or equal to a liquidus temperature of the second metal.

### BRIEF DESCRIPTION OF THE DRAWINGS

FIG. 1 is a flowchart illustrating a method of manufacturing a light-emitting device according to a first embodiment;

FIG. 2 is a schematic side view of a semiconductor light-emitting element;

FIG. 3 is a schematic plan view illustrating a state in which a plurality of semiconductor light-emitting elements are disposed on a carrier plate via an adhesive layer;

FIG. 4 is a schematic side view illustrating the state in which the plurality of semiconductor light-emitting elements are disposed on the carrier plate via the adhesive layer;

FIG. 5 is a schematic longitudinal sectional view of the carrier plate including the plurality of semiconductor light-emitting elements housed in a tray;

FIG. 6 is a schematic side view illustrating the method of manufacturing the light-emitting device according to the first embodiment;

FIG. 7 is a schematic top view of a substrate;

FIG. 8 is a schematic side view of the substrate;

FIG. 9 is a schematic side view of a connection terminal of the substrate;

FIG. 10 is a schematic side view illustrating the method of manufacturing the light-emitting device according to the first embodiment;

FIG. 11 is an enlarged schematic side view illustrating the method of manufacturing the light-emitting device according to the first embodiment;

FIGS. 12A and 12B are enlarged schematic views of the circled portion of FIG. 11;

FIG. 13 is a schematic side view illustrating the method of manufacturing the light-emitting device according to the first embodiment;

FIG. 14 is a schematic side view illustrating the method of manufacturing the light-emitting device according to the first embodiment;

FIG. 15 is a binary phase equilibrium diagram of an Au-Sn alloy;

FIG. 16 is a schematic plan view illustrating the light-emitting device according to the first embodiment;

FIG. 17 is a schematic side view illustrating the light-emitting device according to the first embodiment;

FIG. 18 is a flowchart illustrating a method of manufacturing a light-emitting device according to a second embodiment;

FIG. 19 is an enlarged schematic side view illustrating the method of manufacturing the light-emitting device according to the second embodiment;

FIG. 20 is an enlarged schematic side view illustrating the method of manufacturing the light-emitting device according to the second embodiment;

FIG. 21 is a flowchart illustrating a method of manufacturing a light-emitting device according to a third embodiment; and

FIG. 22 is a partially enlarged schematic side view of a longitudinal section of the light-emitting device according to the third embodiment.

### DETAILED DESCRIPTION

A manufacturing method using a wet plating method disclosed in Patent Document 2 has high mounting accuracy and provides a joint having excellent bonding strength and connection reliability. However, a patterning treatment and a plating device are required. Thus, many facilities are required, and the process tends to become long. Therefore, it is necessary to achieve a lower mounting cost.

According to the present disclosure, a method of manufacturing a light-emitting device with a short process for achieving high mounting accuracy and high bonding strength when mounting the semiconductor light-emitting element can be provided.

Embodiments of the invention will be described below. A method of manufacturing a light-emitting device described below is intended to embody the technical concept of the present invention, and the present invention is not limited to the following disclosure unless otherwise specified. Additionally, the contents described in one embodiment are also applicable to other embodiments and modifications. Further, the sizes, positional relationships, and the like of the members illustrated in the drawings may be exaggerated in order to clarify the description.

### First Embodiment

A method of manufacturing a light-emitting device according to a first embodiment of the present disclosure, as illustrated in FIG. 1, includes a heating step (S101), a preliminary bonding step (S102), and a main bonding step (S105).

### Heating Step

In the heating step (S101), a plurality of semiconductor light-emitting elements 100 are heated to a first temperature that is lower than the solidus temperature of a second metal, and a substrate 200 is also heated to the first temperature. The solidus temperature is a temperature below which a substance becomes completely solid. The plurality of semiconductor light-emitting elements 100 include a plurality of electrodes 120 each including a first metal electrode portion 121 formed of a first metal, and the substrate 200 includes a plurality of connection terminals 220 each including a first metal connection terminal portion 221 formed of the first metal. The electrode 120 of the semiconductor light-emitting element 100 includes a metal multilayer film including a second metal electrode portion 122 formed of the second metal and a third metal electrode portion 123 formed of a third metal positioned between the first metal electrode portion 121 and the second metal electrode portion 122, or the connection terminal 220 of the substrate 200 includes a metal multilayer film including a second metal connection terminal portion 222 formed of the second metal and a third metal connection terminal portion 223 formed of the third metal positioned between the first metal connection terminal portion 221 and the second metal connection terminal portion 222.

The semiconductor light-emitting element 100 is a semiconductor element configured to emit light by itself when a current is supplied, and includes a semiconductor portion 110 and the plurality of electrodes 120 connected to the semiconductor portion 110. The dimension of the semiconductor light-emitting element 100 is, for example, 50 μm square with a thickness of 10.95 μm, specifically, the semiconductor portion 110 is, for example, 50 μm square with a thickness of 8 μm, and each of the plurality of electrodes 120 is, for example, 2.95 μm thick, 42 μm long, and 18 μm wide. The semiconductor light-emitting element 100 is, for example, a light-emitting diode chip that can be flip-chip mounted, and includes the semiconductor portion 110 and positive and negative electrodes 120 on the lower surface of the semiconductor portion 110, and the upper surface opposite to the lower surface serves as a light extraction surface. The light-emitting diode chip is, for example, a blue light-emitting diode chip configured to emit blue light, a green light-emitting diode chip configured to emit green light, a red light-emitting diode chip configured to emit red light, an ultraviolet light-emitting diode chip configured to emit ultraviolet light, an infrared light-emitting diode chip configured to emit infrared light, or the like.

Although not illustrated, the semiconductor portion 110 includes a semiconductor laminate including a first-conductivity-type semiconductor layer, a second-conductivity-type semiconductor layer, and an active layer positioned between the first-conductivity-type semiconductor layer and the second-conductivity-type semiconductor layer. The active layer generates light by direct recombination of electrons and holes therein. The semiconductor portion 110 may include an element substrate on the light extraction surface side of the semiconductor laminate. The semiconductor laminate may include two or more active layers and a tunnel junction layer between the two or more active layers. In this case, there are three or more electrodes 120. The semiconductor laminate may be composed of a crystal of a III-V compound semiconductor or the like, that is, an InAlGaAs-based semiconductor, an InAlGaP-based semiconductor, zinc sulfide, zinc selenide, or an InAlGaN-based semiconductor, for example.

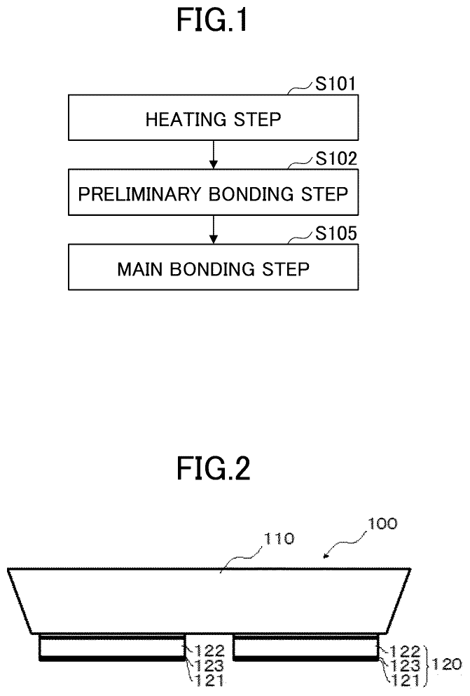

In the example illustrated in FIG. 2, each of the plurality of electrodes 120 of the semiconductor light-emitting element 100 includes the metal multilayer film including the first metal electrode portion 121, the second metal electrode portion 122, and the third metal electrode portion 123 positioned between the first metal electrode portion 121 and the second metal electrode portion 122, and the first metal electrode portion 121 is exposed at the tip of each of the electrodes 120. The melting point of the first metal is higher than the liquidus temperature of the second metal, and the melting point of the third metal is also higher than the liquidus temperature of the second metal. The liquidus temperature is a temperature above which a substance completely enters a liquid phase. The first metal electrode portion 121 includes a metal less likely to rust in air, for example, gold (Au), which is a noble metal, the second metal electrode portion 122 includes tin (Sn), and the third metal electrode portion 123 includes any one metal of the platinum group of ruthenium (Ru), rhodium (Rh), palladium (Pd), osmium (Os), iridium (Ir), or platinum (Pt). The first metal electrode portion 121 prevents oxidation of the second metal electrode portion 122 including Sn and enables good bonding in air. The third metal electrode portion 123 reduces diffusion of a component of the second metal electrode portion 122 into the first metal electrode portion 121 of the electrode 120 during storage before the heating step (S101) or during raising of the temperature to the first temperature and during holding at the first temperature in the heating step (S101), thereby reducing the pressure bonding defect rate in the preliminary bonding step (S102) described later.

Each of the electrodes 120 is, for example, a metal multilayer film in which titanium (Ti) (0.003 μm or greater and 0.015 μm or less thick), a platinum group metal (0.1 μm or greater and 2 μm or less thick), Au (0.1 μm or greater and 1 μm or less thick), an Au—Sn alloy (0.5 μm or greater and 3 μm or less thick) having Sn of 15 wt % or greater and 37 wt % or less, Pt (0.0004 μm or greater and 0.05 μm or less thick, preferably 0.02 μm or greater and 0.05 μm or less thick), and Au (0.0004 μm or greater and 0.1 μm or less thick) are sequentially laminated from the semiconductor portion 110 side. In this case, the first metal electrode portion 121 is formed of Au laminated on Pt, the second metal electrode portion 122 is formed of an Au—Sn alloy, and the third metal electrode portion 123 is formed of Pt positioned between the first metal electrode portion 121 and the second metal electrode portion 122. The first metal electrode portion 121 is exposed at the tip of each of the electrodes 120.

When the second metal electrode portion 122 is formed of an Au—Sn alloy having Sn of 15 wt % or greater and 37 wt % or less, the time required for the main bonding is shorter than the time required when the second metal electrode portion 122 is formed of Sn, and the composition after the main bonding becomes stable. This is because AuSn₄ and AuSn₂ are not formed by the reaction between the second metal and Au of the first metal. The composition of the Au—Sn alloy of the second metal is preferably Sn of 20 wt % or greater and 32 wt % or less, and more preferably Sn of 26 wt % or greater and 32 wt % or less. This is because, in a case where variation in the diffusion of Au of the first metal electrode portion 121 or first metal connection terminal portion 221 occurs in the plane of the substrate 200 when the plurality of semiconductor light-emitting elements are bonded, variation occurs in the bonding of each of the semiconductor light-emitting elements because the slope of the liquidus line is steep when the composition contains more Au than Sn of 20 wt %. Additionally, it is preferable to select the thickness of Au of the first metal electrode portion 121 and first metal connection terminal portion 221 and the composition and thickness of the Au—Sn alloy of the second metal electrode portion 122 so that the ratio of the weight of Sn to the weight of Au contained in a region including the electrode 120 and the connection terminal 220, after the main bonding, that is, a connection metal 130 to be described later, is 0.25 or greater and 0.58 or less. More preferably, the ratio of the weight of Sn to the weight of Au contained in the connection metal 130 after the main bonding is 0.25 or greater and less than 0.408. The occurrence rate of short-circuit failures in the main bonding step (S105) can be reduced, and void formation inside the connection metal 130 can be reduced.

The thickness of the first metal electrode portion 121 of the electrode 120 is adjusted to 0.0004 μm or greater and 0.1 μm or less. The thickness of the third metal electrode portion 123 is adjusted to 0.0004 μm or greater and 0.05 μm or less, preferably 0.02 μm or greater and 0.05 μm or less. In the main bonding step (S105) described later, the first metal and the third metal are mixed with the second metal, so that the first metal electrode portion 121 and the third metal electrode portion 123 do not remain as layers after the main bonding step (S105).

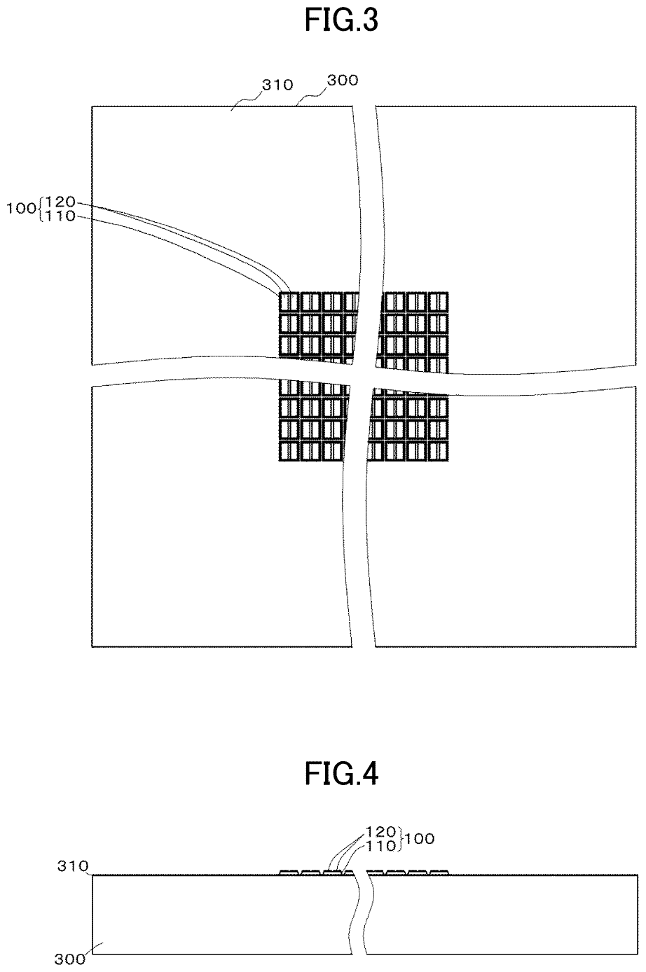

As illustrated in FIGS. 3 and 4, the plurality of semiconductor light-emitting elements 100 are disposed on the main surface of the carrier plate 300 with two or more electrodes 120 facing upward via an adhesive layer 310. The electrodes 120 of the plurality of semiconductor light-emitting elements 100 are disposed to correspond to the arrangement of the plurality of connection terminals 220 of the substrate 200 at the time of alignment in the preliminary bonding step (S102) described later.

Corresponding to the arrangement of the plurality of connection terminals 220 of the substrate 200, for example, 1 million semiconductor light-emitting elements 100 of 50 μm square can be arranged in 1000 rows and 1000 columns per single carrier plate 300. A case where the carrier plate 300 is a plate made of quartz glass of 70 mm square and 1 mm thick and the substrate 200 is an 8-inch silicon (Si) wafer will be described, for example. In this case, when the temperature is raised from a room temperature of about 20° C. to the first temperature, which is, for example, 160° C., the diameter of the substrate 200 increases by about 0.1 mm, but one side of the carrier plate 300 increases by only about 5 μm. The difference of about 100 μm between the amount of increase in the size of the substrate 200 and the amount of increase in the size of the carrier plate 300 is large, in comparison with 50 μm square of the semiconductor light-emitting element 100. That is, it is necessary to dispose the plurality of semiconductor light-emitting elements 100 on the carrier plate 300 while considering a difference in dimensional change due to thermal expansion of the carrier plate 300 and the substrate 200 caused by a temperature difference between the first temperature and the temperature at which the plurality of semiconductor light-emitting elements 100 are disposed on the carrier plate 300. This is because the electrodes 120 of the plurality of semiconductor light-emitting elements 100 and the connection terminals 220 of the substrate 200 are connected together, all at once.

A light-shielding resin or a reflective resin may be disposed between the plurality of semiconductor light-emitting elements 100. Additionally, a translucent sheet may be disposed between the plurality of semiconductor light-emitting elements 100 and the adhesive layer 310.

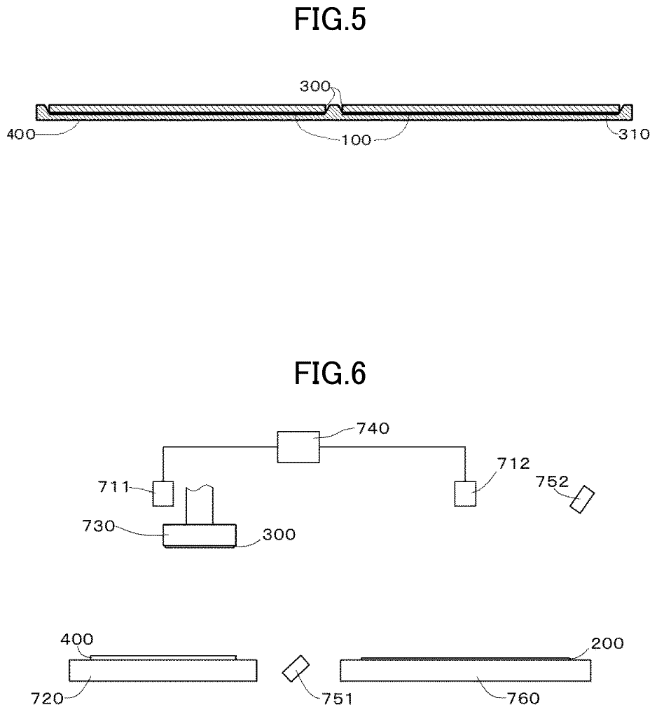

A plurality of carrier plates 300 on which the plurality of semiconductor light-emitting elements 100 are disposed are prepared. As illustrated in FIG. 5, they are housed in a plurality of recesses of a tray 400, having the plurality of recesses on the upper surface, with the electrodes 120 of the semiconductor light-emitting elements 100 facing downward, and placed on a supply stage 720 of a first mounter as illustrated in FIG. 6.

As illustrated in FIGS. 6, 10, and 13, the first mounter includes a first camera 711, a second camera 712, a position control mechanism 740, the supply stage 720, a suction head 730, a first infrared radiation thermometer 751, a mounting stage 760, a second infrared radiation thermometer 752, and an intermediate stage 770. The first camera 711 outputs, to the position control mechanism 740, an image including the shape, in plan view, of the carrier plate 300 including the plurality of semiconductor light-emitting elements 100 housed in the tray 400 provided on the supply stage 720 as image data. The position control mechanism 740 recognizes the positions of four corners of the carrier plate 300 in plan view by using the image data. The position control mechanism 740 outputs a position control signal to the suction head 730 and the supply stage 720 to adjust a relative position between the suction head 730 and the supply stage 720.

The suction head 730 includes a mechanism configured to perform suction of the carrier plate 300 and a mechanism configured to heat the carrier plate 300 held by the suction, for example, a built-in heater. As illustrated in FIG. 6, the suction head 730 holds the carrier plate 300 at a predetermined position on its lower surface by suction from the tray 400 provided on the supply stage 720 and lifts it from the supply stage 720. The plurality of semiconductor light-emitting elements 100 of the lifted carrier plate 300 are heated by the built-in heater of the suction head 730 to raise the temperature to the first temperature and held at the first temperature. The temperature of the semiconductor light-emitting elements 100 can be measured, for example, by using the first infrared radiation thermometer 751 provided below the lower surface of the suction head 730, and the temperature of the semiconductor light-emitting elements 100 is adjusted by Proportional-Integral-Differential control (PID control) using the temperature measured by the first infrared radiation thermometer 751. If the temperature difference between the measured temperature of the semiconductor light-emitting elements 100 and the set first temperature is less than 5° C., the temperature of the semiconductor light-emitting elements 100 can be substantially regarded as the first temperature.

The first temperature is a temperature greater than or equal to the room temperature and less than the solidus temperature of the second metal, that is, the second metal is solid at the first temperature. When the second metal is an Au—Sn alloy having Sn of 11 wt % or greater and 37 wt % or less, the first temperature is, for example, greater than or equal to 120° C. and less than or equal to 220° C., and more preferably greater than or equal to 150° C. and less than or equal to 190° C.

Although the suction head 730 lifts the plurality of semiconductor light-emitting elements 100 via the carrier plate 300, raises the temperature to the first temperature, and holds the semiconductor light-emitting elements at the first temperature, other methods may be employed. For example, the suction head 730 of the first mounter may directly hold and lift the plurality of semiconductor light-emitting elements 100 by suction without using the carrier plate 300, raise the temperature to the first temperature, and hold the semiconductor light-emitting elements at the first temperature. In this case, the tray 400 for housing the plurality of semiconductor light-emitting elements 100 is placed on the supply stage 720 of the first mounter, and the plurality of semiconductor light-emitting elements 100 are arranged in the tray 400 at predetermined intervals with the electrodes 120 facing downward.

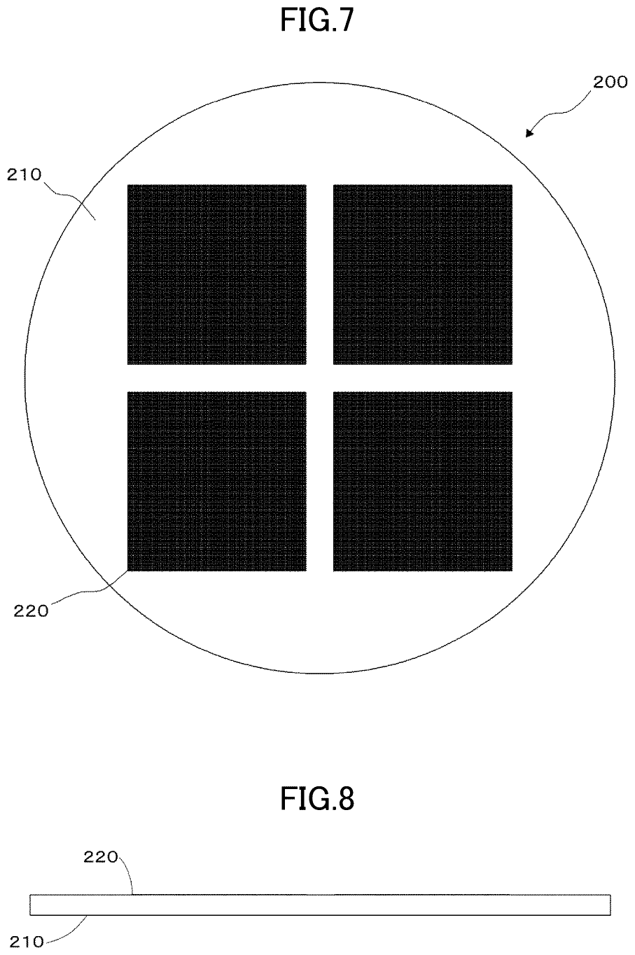

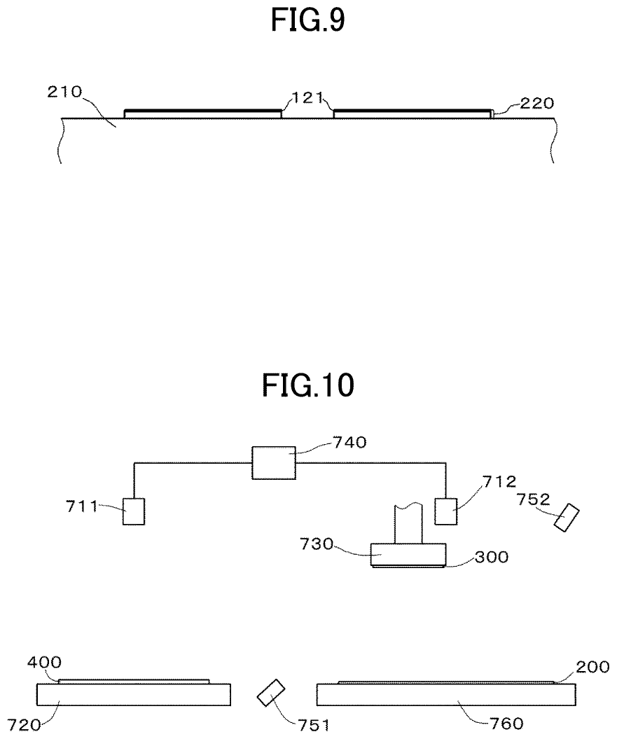

As illustrated in FIGS. 7 to 9, the substrate 200 includes a base 210 and the plurality of connection terminals 220 on the upper surface of the base 210. The substrate 200 may be an integrated circuit (IC) wafer or an IC chip including a large number of elements having functions such as transistors, resistors, and capacitors, or a circuit board such as a printed circuit board. The base 210 may be a single-crystal wafer, a ceramic plate, or a substrate material used for a circuit board. The single-crystal wafer includes at least one single crystal of any one of Si, germanium (Ge), gallium arsenide (GaAs), indium phosphide (InP), gallium nitride (GaN), aluminum nitride (AlN), silicon carbide (SiC), or sapphire. The ceramic plate may be, for example, AlN, Al₂O₃, SiC, or Si₃N₄. The base 210 may include conductor wirings on a surface on which the semiconductor light-emitting elements are mounted and on a surface opposite thereto, or may include vertical interconnect accesses (vias).

Because the plurality of connection terminals 220 are bonded to the plurality of electrodes 120 of the semiconductor light-emitting elements 100, the plurality of connection terminals 220 are arranged to correspond to the plurality of electrodes 120 of the semiconductor light-emitting elements 100. The area of each of the connection terminals 220 as seen in the normal direction of the main surface of the substrate 200 is larger than the area of each of the electrodes 120 that face the connection terminals. Each of the plurality of connection terminals 220 may be formed by laminating a plurality of metal layers. The first metal connection terminal portions 221 are exposed on surfaces of the plurality of connection terminals 220 that are in contact with the plurality of electrodes 120 of the semiconductor light-emitting elements 100.

The substrate 200 is, for example, an 8-inch IC wafer including a single-crystal wafer of Si. The plurality of connection terminals 220 correspond to the plurality of electrodes 120 of each of the plurality of semiconductor light-emitting elements 100. Each of the connection terminals 220 includes the first metal connection terminal portion 221 exposed at the tip. In each of the connection terminals 220, for example, Ti (0.003 μm or greater and 0.015 μm or less thick), Pt (0.1 μm or greater and 2 μm or less thick), and Au (0.1 μm or greater and 1 μm or less thick) are sequentially laminated, and Au is exposed at the tip. Au is formed as the first metal connection terminal portion 221 of the connection terminals 220.

The thickness of the first metal connection terminal portion 221 of the connection terminal 220 is adjusted to 0.1 μm or greater and 1 μm or less, so that the first metal is mixed with the second metal in the main bonding step (S105) described later, and the first metal connection terminal portion 221 does not remain as a layer after the main bonding step (S105).

The substrate 200 is placed on the mounting stage 760 with the plurality of connection terminals 220 facing upward. The surface of the mounting stage 760 on which the substrate 200 is placed is made of flat Si. The mounting stage 760 includes a mechanism configured to hold the substrate 200 and a mechanism configured to heat the held substrate 200. The mechanism configured to hold the substrate 200 may be, for example, a clip or suction. The mechanism configured to heat the substrate 200 may be, for example, a built-in heater.

In parallel with or prior to heating the semiconductor light-emitting element 100, the substrate 200 placed on the mounting stage 760 is also heated by the built-in heater of the mounting stage 760 to raise the temperature to the first temperature, for example, 160° C., and is held at the first temperature. The temperature of the substrate 200 placed on the mounting stage 760 can be measured, for example, by using the second infrared radiation thermometer 752 provided above the mounting stage 760, as illustrated in FIG. 10, and the temperature measured by using the second infrared radiation thermometer 752 is used to adjust the temperature of the substrate 200 by PID control. If the temperature difference between the measured temperature of the substrate 200 and the set first temperature is less than 5° C., the temperature of the substrate 200 can be substantially regarded as the first temperature.

Although the electrode 120 of the semiconductor light-emitting element 100 includes the metal multilayer film including the second metal electrode portion 122 and the third metal electrode portion 123 in the description above, the connection terminal 220 of the substrate 200 may include the metal multilayer film including the second metal connection terminal portion 222 and the third metal connection terminal portion 223. In this case, the electrode 120 of the semiconductor light-emitting element 100 does not include the second metal electrode portion 122. This is because it is sufficient that the second metal electrode portion 122 is included in the electrode 120 or the second metal connection terminal portion 222 is included in the connection terminal 220.

### Preliminary Bonding Step

In the preliminary bonding step (S102), after the electrode 120 held at the first temperature and the connection terminal 220 are aligned, the first metal electrode portion 121 of the electrode 120 and the first metal connection terminal portion 221 of the connection terminal 220 are press-bonded with a first pressure.

The second camera 712 outputs, to the position control mechanism 740, an image including a rectangular shape of an outer edge, in plan view, of an alignment mark for position identification provided outside the region where the plurality of connection terminals 220 of the substrate 200 are present, as image data. The position control mechanism 740 recognizes the positions of the plurality of connection terminals 220 of the substrate 200 by using the image data.

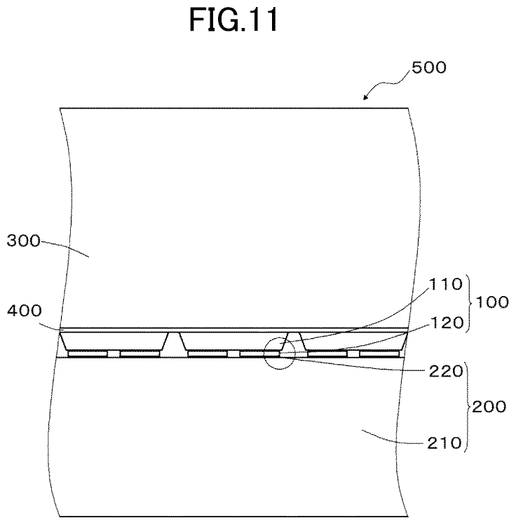

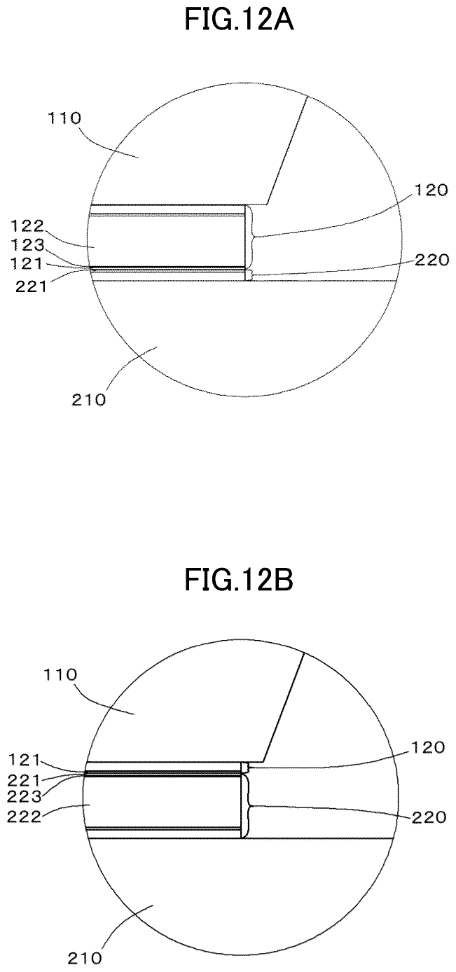

When the suction head 730 is moved to a position over the mounting stage 760, the position control mechanism 740 adjusts the relative position between the suction head 730 and the mounting stage 760 to align the plurality of electrodes 120 and the plurality of connection terminals 220 corresponding to the plurality of electrodes 120. Subsequently, the suction head 730 is moved downward, and then mount, on the substrate 200 placed on the mounting stage 760, the carrier plate 300 including the plurality of semiconductor light-emitting elements 100. At this time, the electrodes 120 of the semiconductor light-emitting elements 100 are held at the first temperature, and the connection terminals 220 of the substrate 200 are also held at the first temperature, and as illustrated in FIG. 11 and FIGS. 12A and 12B, the first metal electrode portion 121 of the electrode 120 and the first metal connection terminal portion 221 of the connection terminal 220 are brought into contact and pressed by the first pressure. This state is held for a first time period, and the first metal electrode portion 121 of the electrode 120 and the first metal connection terminal portion 221 of the connection terminal 220 are press-bonded.

The “press-bond” is pressure welding in which the surfaces of the metals are brought into close contact with each other, and heat and pressure are applied to bond them in a solid state without melting the bonded surfaces, and it is also called solid-phase bonding or solid-phase welding. The first pressure is a value (Unit: Pascal (Pa)) obtained by dividing a load (Unit: Newton (N)) for pressing the suction head 730 to the mounting stage 760 by the sum of the areas (Unit: square meters (m²)) of the plurality of electrodes 120 of the semiconductor light-emitting elements 100.

The first temperature is, for example, 160° C. The first pressure is 3 MPa or greater and 90 MPa or less, and is, for example, 45 MPa. The first time period is 1 second or greater and 60 seconds or less, and is, for example, 10 seconds.

Because the plurality of semiconductor light-emitting elements 100 and the substrate 200 are aligned and brought into contact with each other in a state that can be regarded as the identical temperature, occurrence of a relative positional shift of the electrode 120 and the connection terminal 220 caused by a difference in the coefficient of linear expansion between the substrate 200 and the carrier plate 300 or the like is reduced. Because the electrode 120 and the connection terminal 220 are bonded in a solid state, deformation of the electrode 120 and the connection terminal 220 when pressed is small, and mounting of the plurality of semiconductor light-emitting elements 100 on the substrate 200 can be achieved with high mounting accuracy. Additionally, because the plurality of semiconductor light-emitting elements 100 can be press-bonded together at the same time, it is efficient.

The preliminary bonding step (S102) is performed for all of one or more carrier plates 300 each including the plurality of semiconductor light-emitting elements 100 housed in one tray 400 placed on the supply stage 720 of the first mounter, to form an intermediate body 500. The intermediate body 500 includes the carrier plate 300, the plurality of semiconductor light-emitting elements 100, and the substrate 200, and the first metal electrode portion 121 of the electrode 120 of the semiconductor light-emitting element 100 and the first metal connection terminal portion 221 of the connection terminal 220 of the substrate 200 are press-bonded.

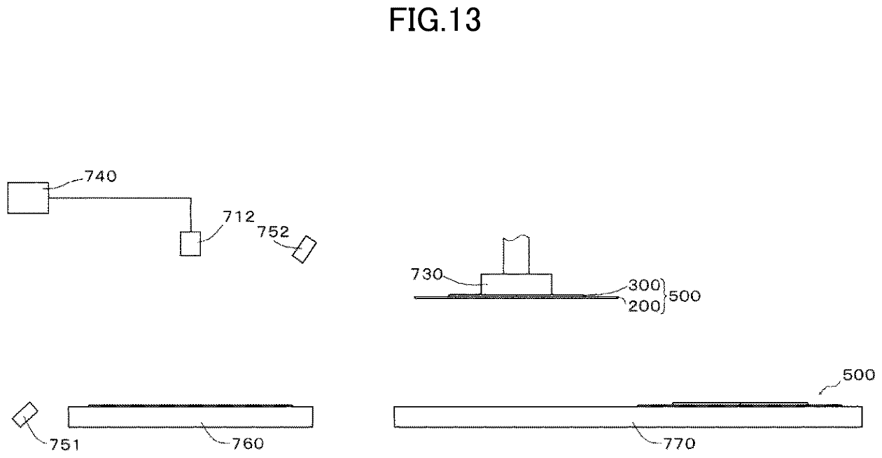

After releasing the holding of the substrate 200, as illustrated in FIG. 13, the intermediate body 500 is held by the suction on the carrier plate 300 side by the suction head 730, lifted from the mounting stage 760, and moved onto the intermediate stage 770.

### Main Bonding Step

In the main bonding step (S105), a second pressure is applied between the plurality of semiconductor light-emitting elements 100 and the substrate 200, the intermediate body 500 is brought to a second temperature, and then the intermediate body 500 is cooled. The second temperature is greater than or equal to the solidus temperature of the second metal and less than or equal to the liquidus temperature of the second metal. The second pressure is less than or equal to the first pressure.

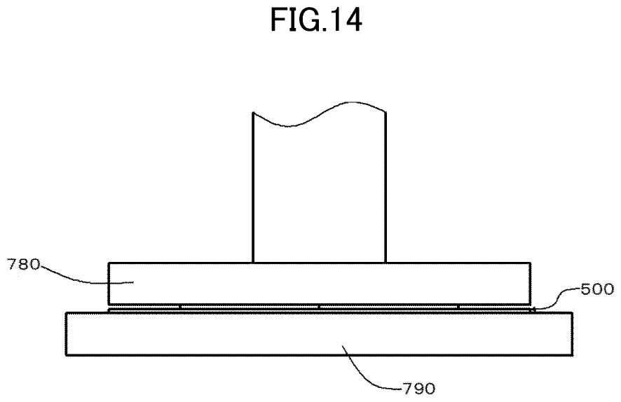

A second mounter includes a heating head 780 and a pedestal 790. The heating head 780 holds and lifts the intermediate body 500 by suction on the carrier plate 300 side. Then, the heating head 780 holding the intermediate body 500 is moved downward to press the intermediate body 500 against the pedestal 790 with the second pressure that is less than or equal to the first pressure applied in the preliminary bonding step (S102), as illustrated in FIG. 14, and the second pressure is applied between the plurality of semiconductor light-emitting elements 100 and the substrate 200. The second pressure is 0.1 MPa or greater and 90 MPa or less, and is, for example, 45 MPa.

Then, the heating head 780 and the pedestal 790 are heated to the second temperature, held for a second time period, and then cooled to room temperature. The second temperature is, for example, 279° C. or greater and 400° C. or less, more preferably, 300° C. or greater and 330° C. or less, and is, for example, 320° C. The second time period is longer than the first time period and less than or equal to 300 seconds, and is, for example, 180 seconds.

Although heat is applied to the intermediate body 500, using the heating head 780 and the pedestal 790, the intermediate body 500 may be placed in an oven set to the second temperature for the second time period. At this time, a weight is placed on the carrier plate 300 so that the second pressure is applied to the intermediate body 500.

At the second temperature, the second metal electrode portion 122 has a liquid phase portion and a solid phase portion. The presence of the solid phase portion reduces the expansion of the second metal electrode portion 122 when pressed by the second pressure, thereby reducing the occurrence rate of short-circuit failure between the electrodes 120.

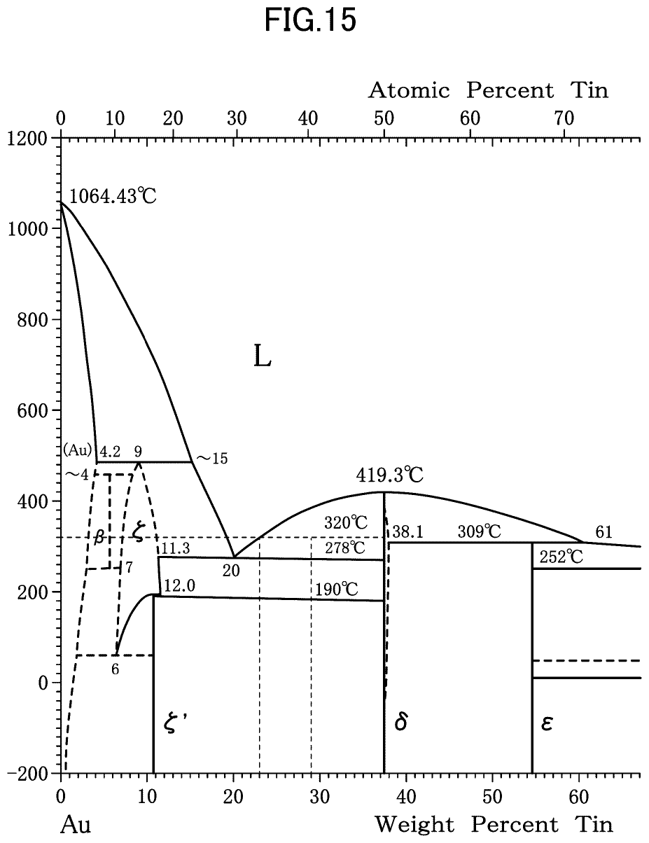

When the second metal is, for example, an Au—Sn alloy layer of 29 wt % Sn, according to the binary phase equilibrium diagram of the Au—Sn alloy (FIG. 15), when the second temperature is 320° C., the solid-phase intermetallic compound AuSn (δ phase, Sn 50 at %) and the liquid-phase Au—Sn alloy of about 23 wt % Sn coexist.

After the first metal of the electrode 120, the first metal of the connection terminal 220, and the third metal are mixed with the second metal, they solidify to form the connection metal 130. The connection metal 130 connects the semiconductor portion 110 to the base 210. When the first metal is Au and the third metal is Pt, a solid phase including the Pt-Au—Sn alloy and the Au—Sn alloy is formed inside the connection metal 130. Neither a layer consisting only of Au nor a layer consisting only of Pt remains inside the connection metal 130. The Au—Sn alloy, which has a relatively low liquidus temperature, covers the Pt-Au—Sn alloy and is exposed to the side surface of the connection metal 130. The interface between the Au—Sn alloy and the Pt-Au—Sn alloy has a complicated and intricate shape. The connection metal 130 has a constriction between the semiconductor portion 110 and the base 210. The position of the constriction is closer to the base 210 than to the semiconductor portion 110 when the second metal electrode portion 122 is included in the electrode 120, and closer to the semiconductor portion 110 than to the base 210 when the second metal connection terminal portion 222 is included in the connection terminal 220. This is because the second temperature is the solidus temperature or greater and the liquidus temperature or less, there is a solid portion of δ-phase AuSn in the second metal electrode portion 122 or the second metal connection terminal portion 222, and the distance between the semiconductor portion 110 and the base 210 is maintained at a certain degree, so that the liquid portion spreads while a gap is formed between the semiconductor portion 110 and the base 210.

Because the plurality of carrier plates 300 on which the plurality of semiconductor light-emitting elements 100 are disposed are processed at the same time, this method is suitable for mass production of light-emitting devices. By raising the temperature to the second temperature greater than or equal to the solidus temperature of the second metal and less than or equal to the liquidus temperature of the second metal and then cooling it, a bonding strength greater than the bonding strength by press-bonding can be obtained. Because the second pressure is less than or equal to the first pressure and the electrode 120 of the semiconductor light-emitting element 100 and the connection terminal 220 of the substrate 200 are press-bonded and then heated, the relative positional relationship between the electrode 120 and the connection terminal 220 does not change or changes little, and high mounting accuracy can be achieved. In comparison with a manufacturing method using a wet plating method, there is no patterning process and plating process, and the process can be shortened.

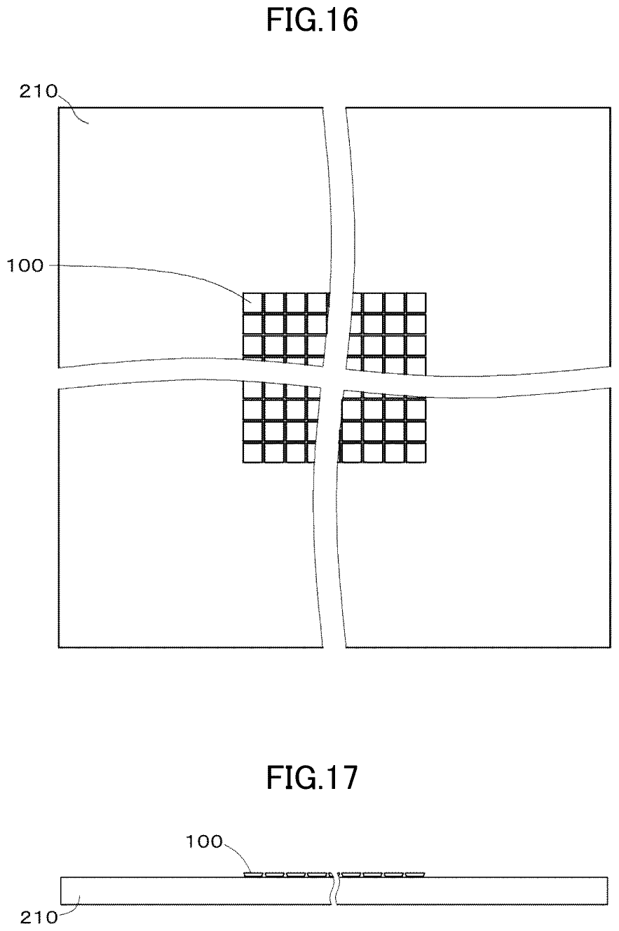

After the main bonding step (S105), the plurality of carrier plates 300 are peeled off and removed together with the adhesive layer 310, and further the substrate 200 is cut, thereby simultaneously forming the plurality of light-emitting devices as illustrated in FIGS. 16 and 17. Dicing can be used as the cutting method, for example.

### Second Embodiment

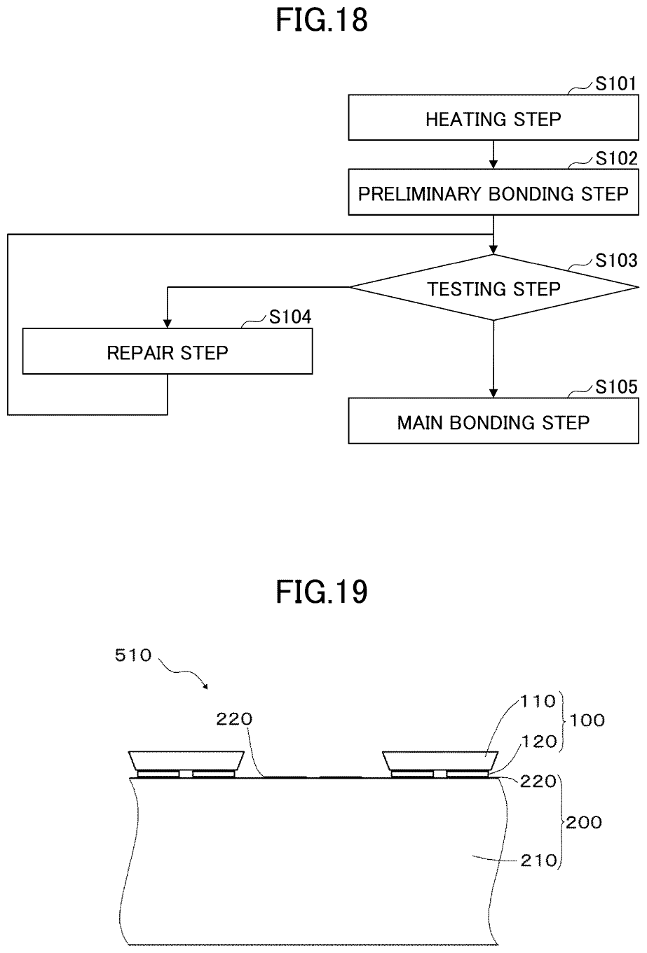

A method of manufacturing a light-emitting device according to a second embodiment is the same as that of the first embodiment up to the preliminary bonding step (S102). The method of manufacturing the light-emitting device according to the second embodiment includes a testing step (S103) after the preliminary bonding step (S102) and before the main bonding step (S105), as illustrated in FIG. 18. Furthermore, the method of manufacturing the light-emitting device according to the second embodiment includes a repair step (S104) when there is a semiconductor light-emitting element 100 that is determined to have failed the test. In the second embodiment, a test object 510 includes the plurality of semiconductor light-emitting elements 100 and the substrate 200, and the first metal electrode portion 121 of the electrode 120 of the semiconductor light-emitting element 100 and the first metal connection terminal portion 221 of the connection terminal 220 of the substrate 200 are press-bonded.

### Testing Step

After the preliminary bonding step (S102), the carrier plate 300 and the adhesive layer 310 are peeled off and removed to form the test object 510. Then, each of the plurality of semiconductor light-emitting elements 100 is irradiated with excitation light, and a photoluminescence test for measuring the emission intensity, spectrum, and the like of each of the semiconductor light-emitting elements 100 is performed. The excitation light has a wavelength that generates electron-hole pairs in the active layer of the semiconductor portion 110. The photoluminescence test is a method of observing light generated when a substance is irradiated with light and the photoexcited electrons return to the ground state. A semiconductor light-emitting element 100 exhibiting a measurement value outside a predetermined numerical range is determined to have failed the test, and its position is stored in a storage device.

Although the photoluminescence test is used above, if the substrate 200 is provided with wiring for energizing the plurality of semiconductor light-emitting elements 100, each of the semiconductor light-emitting elements 100 may be energized to emit light, and its light emission intensity, spectrum, and the like may be measured.

### Repair Step

The semiconductor light-emitting element 100 located at the position stored in the storage device in the testing step (S103) is removed from the test object 510. At this time, as illustrated in FIG. 19, the connection terminal 220 of the substrate 200 that is press-bonded with the electrode 120 of the removed semiconductor light-emitting element 100 remains in the test object 510. As the removal method, for example, a method using a vacuum collet, a method using laser light irradiation, a method using an adhesive sheet, and the like may be used.

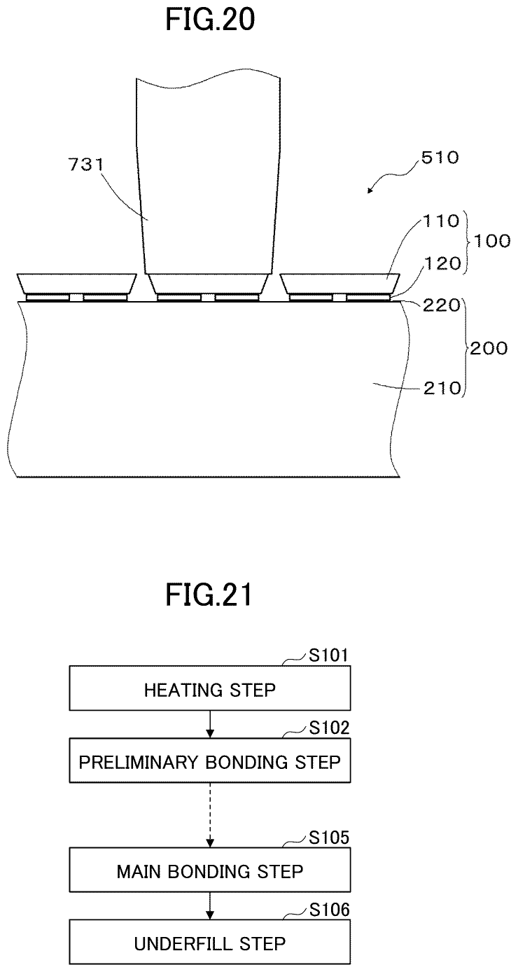

Next, the test object 510 after the removal of the semiconductor light-emitting element 100 determined to have failed the test is returned to the mounting stage 760, and the temperature is raised to the first temperature. In parallel, a new semiconductor light-emitting element 100 is aligned and lifted up by a vacuum collet 731, and the temperature is raised to the first temperature. Then, as illustrated in FIG. 20, the electrode 120 of the new semiconductor light-emitting element 100 is aligned and press-bonded to the connection terminal 220 of the substrate 200 in the region where the semiconductor light-emitting element 100 determined to have failed the test is removed, thereby replacing it with the new semiconductor light-emitting element 100.

The newly press-bonded semiconductor light-emitting element 100 is caused to emit light, and it is confirmed whether the semiconductor light-emitting element 100 exhibits a measured value outside a predetermined numerical range. If there is no semiconductor light-emitting element 100 determined to have failed the test, the process proceeds to the main bonding step (S105). If there is any semiconductor light-emitting element 100 determined to have failed the test, the repair step (S104) and the testing step (S103) are repeated until there are no more semiconductor light-emitting elements 100 determined to have failed the test. By including the testing step (S103) and the repair step (S104), the lighting rate of the plurality of semiconductor light-emitting elements 100 in one light-emitting device can be made 100% or close to 100%.

### Third Embodiment

A method of manufacturing a light-emitting device according to a third embodiment is the same as that of the first embodiment or the second embodiment up to the main bonding step (S105). As illustrated in FIG. 21, after the main bonding step (S105), the method of manufacturing the light-emitting device according to the third embodiment includes an underfill step (S106) in which a gap between the semiconductor portions 110 and the base 210 is filled and sealed with an underfill 600 after the plurality of carrier plates 300 are peeled off and removed together with the adhesive layer 310. This is to reinforce the connection between the semiconductor light-emitting elements 100 and the substrate 200. Additionally, the underfill 600 has a function of protecting the connection metal 130 from moisture or the like from the outside.

The material of the underfill 600 preferably has a low viscosity, a low thixotropic property, a defoaming property, and wettability before curing, and preferably has a high adhesive strength, toughness, a moderate flexibility, a low coefficient of linear expansion, and a high glass transition temperature after curing. The underfill 600 before curing includes a filler and a diluent in addition to a resin material.

The resin material used for the underfill 600 includes epoxy resins, silicone resins, modified silicone resins, polyurethane resins, oxetane resins, acrylic resins, polycarbonate resins, polyimide resins, polyester resins, or the like. Thermosetting resins, such as silicone resins, modified silicone resins, or epoxy resins, having a good translucency, are preferable.

In order to impart light reflectivity to the underfill 600, the filler preferably includes particles of an inorganic material, such as titanium oxide, aluminum oxide, zinc oxide, barium carbonate, barium sulfate, boron nitride, aluminum nitride, or glass filler. The median diameter of these particles is preferably 1 nm or greater and 200 nm or less, more preferably 100 nm or less, and particularly preferably 50 nm or less. The ratio of the filler to the resin material is adjusted to control the thermal expansion coefficient of the underfill 600 after curing.

As the diluent, for example, an organic solvent, such as an aliphatic hydrocarbon solvent (such as tridecane, heptane, or hexane), an aromatic hydrocarbon solvent (such as xylene, toluene, or benzene), a halogenated hydrocarbon solvent (such as trichloroethylene, perchloroethylene, or methylene chloride), an ester solvent (such as ethyl acetate), a ketone solvent (such as methyl isobutyl ketone or methyl ethyl ketone), an alcohol solvent (such as ethanol, isopropanol, or butanol), or the like is used. The boiling point of the diluent is preferably 100° C. or greater and 350° C. or less, more preferably 150° C. or greater and 300° C. or less. The diluent is used to reduce the viscosity of the underfill 600 before curing.

The underfill 600 before curing is supplied around the plurality of semiconductor portions 110 on the upper surface of the base 210. The gap between the semiconductor portions 110 and the base 210 is filled with the underfill 600 by using a capillary phenomenon. Subsequently, the resin material included in the underfill 600 is thermally cured. Subsequently, the substrate 200 is cut to form the plurality of light-emitting devices simultaneously.

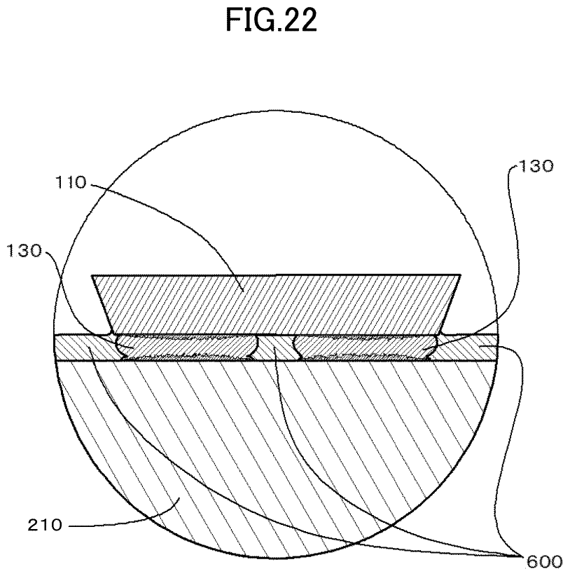

Through the underfill step (S106), as illustrated in FIG. 22, the underfill 600 is disposed in contact with the lower surface of the semiconductor portion 110, the upper surface of the base 210, and the side surface of the connection metal 130. Because the connection metal 130 has a constriction between the semiconductor portion 110 and the base 210, a recess is formed on the side surface of the connection metal 130, and the intersection line between the side surface of the connection metal 130 and the longitudinal section includes a portion bent at an acute angle. The underfill 600 also enters the recess and cures, thereby producing an anchor effect. This enhances the function of the underfill 600 for reinforcing the connection between the semiconductor light-emitting elements 100 and the substrate 200.

The present disclosure includes the following configurations.

(1) A method of manufacturing a light-emitting device including:
a heating step of heating a plurality of semiconductor light-emitting elements and a substrate to a first temperature, each of the plurality of semiconductor light-emitting elements including a plurality of electrodes, the substrate including a plurality of connection terminals, and each of the plurality of electrodes including a first metal electrode portion formed of a first metal, and each of the plurality of connection terminals including a first metal connection terminal portion formed of the first metal;
a preliminary bonding step of press-bonding the first metal electrode portion to the first metal connection terminal portion with a first pressure to form an intermediate body after aligning the plurality of electrodes and the plurality of connection terminals while maintaining the first temperature; and
a main bonding step of applying a second pressure between the substrate and the plurality of semiconductor light-emitting elements to bring the intermediate body to a second temperature and then cooling the intermediate body, the second pressure being less than or equal to the first pressure,
wherein each of the plurality of electrodes further includes a metal multilayer film including:
   a second metal electrode portion formed of a second metal; and
   a third metal electrode portion formed of a
   third metal, the third metal electrode portion being positioned between the first metal electrode portion and the second metal electrode portion, or
each of the plurality of connection terminals further includes a metal multilayer film including:
   a second metal connection terminal portion formed of the second metal; and
   a third metal connection terminal portion formed of the third metal, the third metal connection terminal portion being positioned between the first metal connection terminal portion and the second metal connection terminal portion, and
wherein the first temperature is lower than a solidus temperature of the second metal, and the second temperature is greater than or equal to the solidus temperature of the second metal and less than or equal to a liquidus temperature of the second metal.

(2) The method of manufacturing the light-emitting device as described in (1), wherein a second time period for applying the second pressure between the substrate and the plurality of semiconductor light-emitting elements in the main bonding step is longer than a first time period in the preliminary bonding step.

(3) The method of manufacturing the light-emitting device as described in (1) or (2), wherein the first pressure is 3 MPa or greater and 90 MPa or less, and the second pressure is 0.1 MPa or greater and 90 MPa or less.

(4) The method of manufacturing the light-emitting device as described in any one of (1) to (3), wherein the first metal is Au, the second metal is an Au—Sn alloy with Sn of 26 wt % or greater and 32 wt % or less, and the third metal includes any one of Ru, Rh, Pd, Os, Ir, or Pt.

(5) The method of manufacturing the light-emitting device as described in (4), wherein the first temperature is 150° C. or greater and 190° C. or less, and the second temperature is 300° C. or greater and 330° C. or less.

(6) The method of manufacturing the light-emitting device as described in any one of (1) to (5), further comprising:
a testing step of testing the plurality of semiconductor light-emitting elements to determine whether each of the plurality of semiconductor light-emitting elements fails the testing; and
a repair step of replacing a semiconductor light-emitting element determined in the testing step to have failed the testing among the plurality of semiconductor light-emitting elements,
wherein the testing step and the repair step are performed between the preliminary bonding step and main bonding step.

(7) The method of manufacturing the light-emitting device as described in any one of (1) to (6),
wherein the substrate includes a base, the plurality of connection terminals are provided on an upper surface of the base, each of the plurality of semiconductor light-emitting elements includes a semiconductor portion, the plurality of electrodes are provided on a lower surface of the semiconductor portion, and
wherein the method further comprising an underfill step of filling a gap between the semiconductor portion and the substrate with an underfill after the main bonding step.

(8) A light-emitting device including:
a semiconductor portion configured to generate light;
a base;
a connection metal for connecting the semiconductor portion to the base; and
an underfill disposed in contact with a lower surface of the semiconductor portion, an upper surface of the base, and a side surface of the connection metal,
wherein the connection metal has a constriction in a longitudinal section.

(9) The light-emitting device as described in (8), wherein the connection metal includes Au and Sn, and a ratio of a weight of Sn to a weight of Au included in the connection metal is greater than or equal to 0.25 and less than 0.408.

What is claimed is:

1. A method of manufacturing a light-emitting device comprising:
heating a plurality of semiconductor light-emitting elements and a substrate to a first temperature, each of the plurality of semiconductor light-emitting elements including a plurality of electrodes, the substrate including a plurality of connection terminals, each of the plurality of electrodes including a first metal electrode portion formed of a first metal, and each of the plurality of connection terminals including a first metal connection terminal portion formed of the first metal;
aligning the plurality of electrodes and the plurality of connection terminals while maintaining the first temperature;
press-bonding the first metal electrode portion to the first metal connection terminal portion with a first pressure to form an intermediate body after the aligning of the plurality of electrodes and the plurality of connection terminals; and
applying a second pressure between the substrate and the plurality of semiconductor light-emitting elements to bring the intermediate body to a second temperature and then cooling the intermediate body, the second pressure being less than or equal to the first pressure,
wherein each of the plurality of electrodes further includes a metal multilayer film including:
a second metal electrode portion formed of a second metal; and
a third metal electrode portion formed of a third metal, the third metal electrode portion being positioned between the first metal electrode portion and the second metal electrode portion, or
each of the plurality of connection terminals further includes a metal multilayer film including:
a second metal connection terminal portion formed of the second metal; and
a third metal connection terminal portion formed of the third metal, the third metal connection terminal portion being positioned between the first metal connection terminal portion and the second metal connection terminal portion, and
wherein the first temperature is lower than a solidus temperature of the second metal, and the second temperature is greater than or equal to the solidus temperature of the second metal and less than or equal to a liquidus temperature of the second metal.

2. The method of manufacturing the light-emitting device as claimed in claim 1, wherein a second time period for applying the second pressure between the substrate and the plurality of semiconductor light-emitting elements in the applying of the second pressure is longer than a first time period for the press-bonding.

3. The method of manufacturing the light-emitting device as claimed in claim 1, wherein the first metal is Au, the second metal is an Au—Sn alloy with Sn of 26 wt % or greater and 32 wt % or less, and the third metal includes any one of Ru, Rh, Pd, Os, Ir, or Pt.

4. The method of manufacturing the light-emitting device as claimed in claim 3, wherein the first temperature is 150° C. or greater and 190° C. or less, and the second temperature is 300° C. or greater and 330° C. or less.

5. The method of manufacturing the light-emitting device as claimed in claim 1, wherein the first pressure is 3 MPa or greater and 90 MPa or less, and the second pressure is 0.1 MPa or greater and 90 MPa or less.

6. The method of manufacturing the light-emitting device as claimed in claim 1, further comprising:
testing the plurality of semiconductor light-emitting elements to determine whether each of the plurality of semiconductor light-emitting elements fails the testing; and
replacing a semiconductor light-emitting element determined to have failed the testing among the plurality of semiconductor light-emitting elements,
wherein the testing and the replacing are performed between the press-bonding and the applying of the second pressure.

7. The method of manufacturing the light-emitting device as claimed in claim 1,
wherein the substrate includes a base, the plurality of connection terminals are provided on an upper surface of the base, each of the plurality of semiconductor light-emitting elements includes a semiconductor portion, and the plurality of electrodes are provided on a lower surface of the semiconductor portion, and
wherein the method further comprises filling a gap between the semiconductor portion and the substrate with an underfill after the cooling of the intermediate body.

8. A light-emitting device comprising:
a semiconductor portion configured to generate light;
a base;
a connection metal for connecting the semiconductor portion to the base; and
an underfill disposed in contact with a lower surface of the semiconductor portion, an upper surface of the base, and a side surface of the connection metal,
wherein the connection metal has a constriction in a longitudinal section of the connection metal.

9. The light-emitting device as claimed in claim 8, wherein the connection metal includes Au and Sn, and a ratio of a weight of Sn to a weight of Au included in the connection metal is greater than or equal to 0.25 and less than 0.408.

10. The method of manufacturing the light-emitting device as claimed in claim 1, wherein the applying of the second pressure includes placing the intermediate body on a pedestal and pressing the intermediate body against the pedestal with the second pressure.
